(19) United States
(12) Patent Application Publication
(10) Pub. No.: US 2001/0005142 A1
(43) Pub. Date: Jun. 28, 2001

(54) Contact pin elastic body for supporting the same and socket having them for testing module

(75) Inventor: Sang Hun Lee, Seoul (KR)

Correspondence Address: AKIN, GUMP, STRAUSS, HAUER & FELD, L.L.P., ONE COMMERCE SQUARE, 2005 MARKET STREET, SUITE 2200, PHILADELPHIA, PA, 19103, US

(73) Assignee: WOOYOUNG Co. Ltd.

(21) Appl. No.: 09/785,825

(22) Filed: Feb. 16, 2001

(30) Foreign Application Priority Data
Nov. 27, 1999 (KR) 2000-70867

(51) Int. Cl. G01R 31/02

(52) U.S. Cl. 324/754

(57) ABSTRACT

The present invention relates to a socket for testing a module, including a contact pin that is an electrical connecting device for mutually connecting a connecting pin of a module to a terminal of a printed circuit board in testing the module and an elastic body for supporting the contact pin. The socket according to the present invention includes: one or more slots 45 formed in said contact pin housing, penetrating the contact pin housing 40 from an upper surface 42 to a lower surface 44 with one side surface 43 thereof opened and having a room other than a room for receiving the contact pin 20; and a channel 41 having a groove 46 for fixing the elastic body 50 and formed at a center portion of said contact pin housing along a length direction thereof to cross all of said slots, wherein the elastic body 50 is inserted into the channel 41 and is fixed to the groove to perform a function of supporting the contact pin and a function as a rotating axis of the contact pin, and wherein the contact pin 20 is inserted into the slots and is supported by the elastic body to electrically connect the connecting pin 31 of the module 30 to the terminal 60 of the PCB. Therefore, a good contact can be maintained, the electrical length can be very short and the lifetime of the socket can be elongated.

### TECHNICAL FIELD

The present invention relates to a socket for testing a module. More specifically, the present invention relates to a socket for testing a module in which by way of improving the structure of a contact pin and a elastic body for supporting the contact pin, an electrical connecting path between a body to be tested and a printed circuit board can be reduced to improve high frequency characteristic, a good electrical connection can be maintained and lifetime of the socket can be elongated.

### BACKGROUND OF THE INVENTION

In general, a module means a set of elements or a set of programs having one function. The module is built in an advanced electronic apparatus having various processing functions such as a computer for processing various language processes. Package devices such as various semiconductor devices are mounted on a printed circuit board (PCB) and are connected to a panel via a plurality of connecting pins. At that time, the electrical connecting devices for the connecting pins of the module to the terminals of the PCB, namely contact pins are necessary.

In order to design such contact pins, following four items must be taken into consideration. First, the contacting state must be maintained well. So, the contact sections is required to be contact with the connecting pins of the module and the terminals of the PCB, by way of wiping action. Second, the electrical length between the contact points must be as short as possible. Because when the electrical length is long in a module tester for high frequency, inductance of the contact pin get greater to increase the impedance thereof, the electrical length must be taken into consideration very importantly. Third, the lifetime of the contact pin and the elastic body for supporting the contact pin must be long and the structure must be simple. Because when the lifetime of any one of the contact pins is expired, the whole socket must be exchanged, the lifetime must be taken into consideration very importantly.

Conventionally, by means of considering such items, various structures have been developed and used. FIG. 1 is a cross-sectional view of an important part of the socket including the conventional contact pin.

The contact pin shown in FIG. 1 was developed by JohnsTech International Corporation and is widely used in the socket for testing a module. The contact pin 10 shown in FIG. 1 is formed of a thin and flat metal sheet. The elastic bodies 11, 12 are inserted into the elastic body-inserting section formed in the upper and the lower portion of one side to fix the contact pin 10 to the contact pin housing. That is, two elastic bodies 11, 12 have a function of providing the restoring force and a function of the rotating axis of the contact pin 10 when the contact pin 10 is rotated.

However, because the socket shown in FIG. 1 must have the contact pin 10 formed with two elastic body-inserting sections and two elastic bodies 11, 12 for supporting the contact pin, there is a defect that the structure thereof is complex.

### SUMMARY OF THE INVENTION

Therefore, the present invention is made in order to solve the conventional problems described above and an object of the present invention is to provide a contact pin in which a good contact can be maintained, a electrical length thereof is very short and the lifetime thereof can be elongated, an elastic body for supporting the contact pin and a socket including them.

The present invention relates to a socket for testing a module, including a contact pin that is an electrical connecting device for mutually connecting a connecting pin of a module to a terminal of a printed circuit board in testing the module and an elastic body for supporting the contact pin.

A contact pin according to the present invention is made of a thin and flat metal sheet and includes: an elastic body-inserting section formed such that most part of either left or right side of a center of said contact pin is opened; a first contact section opposite to said elastic body-inserting section and formed to get in contact with said connecting pin of said module; and a second contact section formed at lower end of said elastic body-inserting section to get in contact with said terminal of said PCB, wherein said elastic body-inserting section is formed in a shape longish from up to down and holding projections are formed at both end portions of said elastic body-inserting section, said holding projections supporting an elastic body to be inserted into said elastic body-inserting section so as not to easily separate said elastic body from said elastic body-inserting section.

An elastic body according to the present invention includes: a supporting member formed in a shape longish from up to down to be inserted into and fixed to a contact pin inserting section of a contact pin, said contact pin inserting section having a space of a shape longish from up to down and holding projections formed at both end portions thereof, respectively; and a fixing member formed as one body with said supporting member and perpendicularly to said supporting member at a upper portion of said supporting member, said fixing member being inserted into and fixed to a contact pin housing for fixing said contact pin, wherein said elastic body provides an elastic force and a restoring force to said contact pin, by way of being contracted, expanded and restored about a portion where said supporting member and said fixing member are crossed.

Also, a socket according to the present invention includes: one or more slots formed in said contact pin housing, said slots penetrating said contact pin housing from up to down with one side thereof opened and having a room other than a room for receiving said contact pin; and a channel formed with a groove for fixing said elastic body and formed at a center of said contact pin housing along a length direction thereof to cross all of said slots, wherein said elastic body is inserted into said channel and consists of a supporting member formed in a shape longish from up to down and a fixing member formed as one body with said supporting member and formed perpendicularly to said supporting member at a upper portion of said supporting member, to be fixed to said groove and to serve as a rotating axis of said contact pin, and wherein said contact pin includes an elastic body-inserting section formed in a shape longish from up to down to be coupled to said supporting member of said elastic body and having holding projections formed at both end portions thereof not to easily separate said elastic body from said elastic body-inserting section, said contact pin being inserted into said slots and being supported by said elastic body to electrically connect said connecting pin of said module to said terminal of said PCB.

### BRIEF DESCRIPTION OF THE DRAWINGS

The embodiments of the present invention will be explained with reference to the accompanying drawings, in which:

FIG. 1 is a cross-sectional view of an important part of the socket including the contact pin according to the conventional art;

FIG. 2 is a perspective view of a contact pin to be provided in a socket according to the present invention;

FIG. 3 is a perspective view of an elastic body for supporting the socket shown in FIG. 2;

FIG. 4 is a plan view of a contact pin housing used in the socket according to the present invention;

FIG. 5 is a cross-sectional view taken along line A-A in the contact pin housing shown in FIG. 4;

FIG. 6 is a perspective and cross-sectional view showing a state that the contact pins are provided in the contact pin housing of the socket according to the present invention;

FIG. 7 is a cross-sectional view of the socket in which the contact pin housing shown in FIG. 6 is provided; and

FIG. 8 is a cross-sectional view showing a state that a module is inserted into the socket shown in FIG. 7.

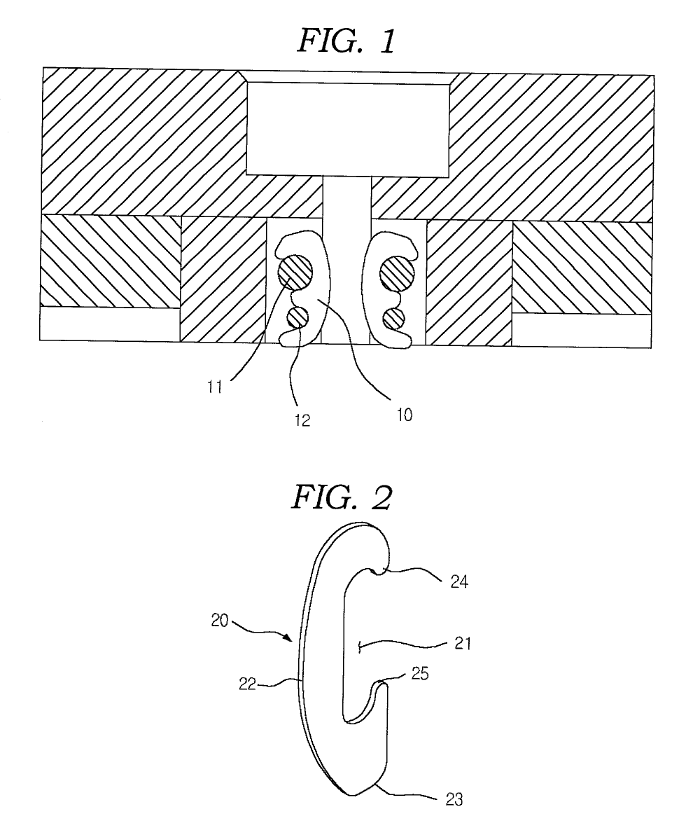

### DETAILED DESCRIPTION OF THE INVENTION

The above objects, other objects, features and advantages of the present invention will be better understood from the following description taken in conjunction with the attached drawings.

Now, embodiments of a contact pin, an elastic body for supporting the contact pin and a socket including them according to the present invention will be explained in detail with reference to the attached drawings.

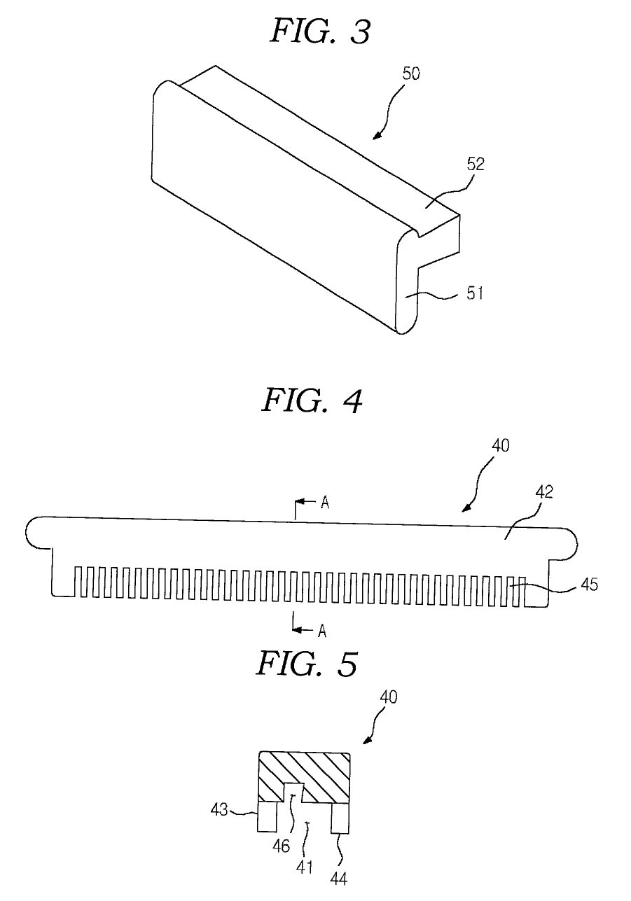

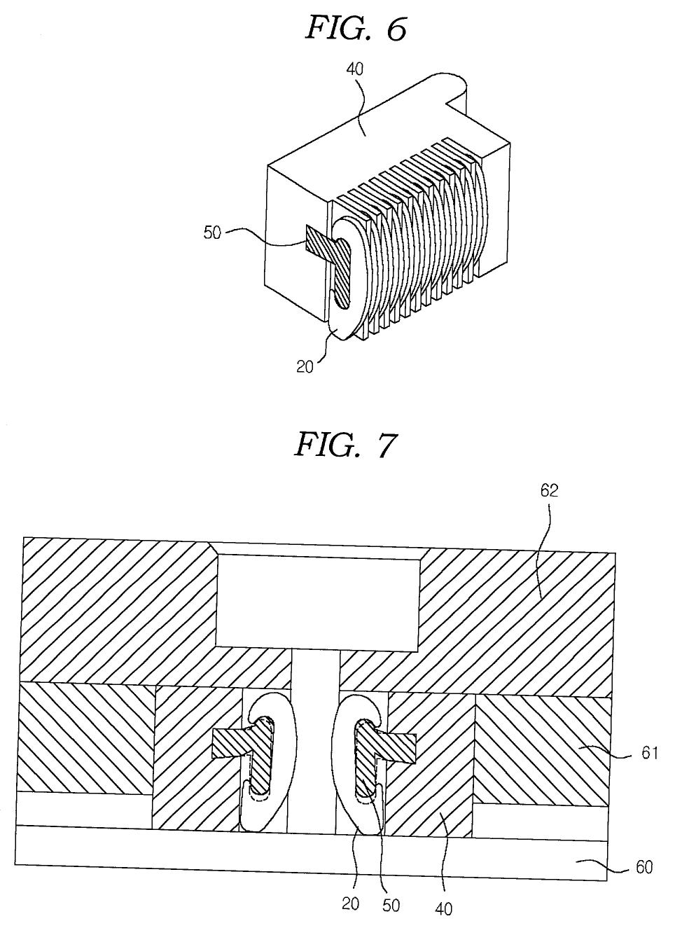

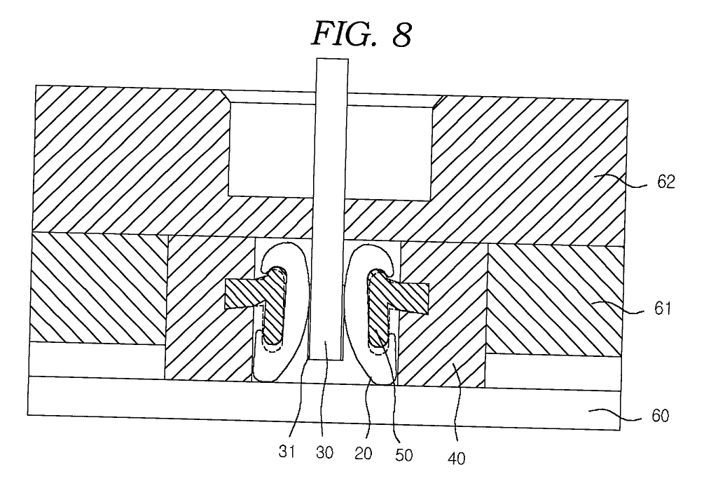

FIG. 2 is a perspective view of a contact pin to be provided in a socket according to the present invention; FIG. 3 is a perspective view of an elastic body for supporting the socket shown in FIG. 2; FIG. 4 is a plan view of a contact pin housing used in the socket according to the present invention; FIG. 5 is a cross-sectional view taken along line A-A in the contact pin housing shown in FIG. 4; FIG. 6 is a perspective and cross-sectional view showing a state that the contact pins are provided in the contact pin housing of the socket according to the present invention; FIG. 7 is a cross-sectional view of the socket in which the contact pin housing shown in FIG. 6 is provided; and FIG. 8 is a cross-sectional view showing a state that a module is inserted into the socket shown in FIG. 7.

As shown in FIG. 2, the contact pin 20 is formed of a thin and flat metal sheet. The contact pin 20 includes an elastic body-inserting section 21 formed in a shape that most part of either right or left (right in FIG. 2) of the center is opened, a first contact section 22 formed at a side (left in FIG. 2) opposite to the elastic body-inserting section 21 and in contact with a connecting pin 31 of a module 30, and a second contact section 23 formed at lower end of the elastic body-inserting section 21 and in contact with a terminal 60 of PCB.

The elastic body-inserting section 21 is formed in a space type having a shape longish from up to down and a first holding projection 24 and a second holding projection 25 are formed at both end portions thereof, respectively. The first holding projection 24 and the second holding projection 25 enable the contact pin 20 to be firmly fixed to an elastic body 50 for supporting the contact pin. The second holding projection 25 positioned at the lower part is formed more greatly than the first holding projection 24 positioned at the upper part.

The first contact section 22 is formed in a curved surface shape, at most projected position of the outer side surface and is positioned at a little upper part from the center. That is, the contact pin 20 is formed such that the first contact section 22 is positioned at a little upper part of the outer side surface. Also, the second contact section 23 is formed in a curved surface shape, at the lowest position of the outer side surface and is formed to maintain wiping with the PCB terminal 60 in large area.

Also, the first contact section 22 and the second contact section 23 of the contact pin 20 are formed such that first contact section 22 is projected a little out of the side surface 43 of the contact pin housing 40 and the second contact section 23 is projected a little out of the lower surface 44, thereby to get easily in contact with the connecting pin 31 of the module 30 and the PCB terminal 60, when the elastic body 50 is inserted into the channel 41 of the contact pin housing 40 and the elastic body-inserting section 21 of the contact pin 20 is closely coupled to the elastic body 50.

In order to design such contact pin, following items are taken into consideration.

First, when pressed by way of insertion of the module 30 into the contact pin housing 40, the contact pin 20 is rotated about the elastic body 50 and the first contact section 22 and the second contact section 23 carry out wiping action to get in contact with the connecting pin 31 and the PCB terminal 60, respectively. In the present invention, the rotation axis of the contact pin 20 is one and the distance between the rotation axis and the contact sections is maximum, so that the radius of the rotation gets greater to result in enough wiping action at the contact sections.

Second, the structure that the electrical path between the first contact section 22 and the second contact section 23 is on a straight line and that the vertical and the horizontal distance between the contact sections are reduced is adopted, thereby to minimize the electrical length between the contact sections. This means that the contact pin according to the present invention 20 is suitable for the socket for testing a module at high frequency.

Third, the structure that while the contact pin 20 is rotated about the elastic body, the contact pin 20 is provided with elastic force so that torsion deforming the contact pin 20 due to repeated use thereof can be minimized, is adopted. Such structure can elongate the lifetime of the contact pin 20 and in addition, can elongate the lifetime of the socket that is an expensive device.

FIG. 3 is a perspective view of the elastic body 50 for supporting the contact pin 20. As shown in FIG. 3, the elastic body 50 is a rubber member having a predetermined elastic force and restoring force. The elastic body 50 consists of a supporting member 51 inserted into the elastic body-inserting section 21 of the contact pin 20 to support the contact pin 20 and a fixing member 52 formed in one body with the supporting member 51 to fix the elastic body 50 to the contact pin housing 40. The supporting member 51 is formed in a shape longish from up to down to be inserted into the elastic body-inserting section 21 and to engage with the first and the second holding projection 24, 25, thereby not to be released. The fixing member 52 is formed at the upper portion of the supporting member 51 and is nearly perpendicular to the supporting member 51. The fixing member 52 has a predetermined thickness and a predetermined length to be inserted into and fixed to the contact pin housing 40. The supporting member 51 and the fixing member 52 of the elastic body 50 constructed like such is expanded, contracted and restored about their crossed portion to provide elastic force and restoring force to the contact pin 20.

FIG. 4 and 5 are a plan view and a cross-sectional view of the contact pin housing 40 to receive the contact pin 20. As shown in FIG. 4, one or more slots 45 are formed at the housing 40, to receive the contact pin 20. The slots 45 penetrate the housing 40 from the upper surface 42 to the lower surface 44, with the side surface 43 thereof opened.

As shown in FIG. 5, a channel 41 is formed at the center portion of the housing 40 to receive the elastic body 50 and crosses the whole slots 45. A groove 46 which the fixing member 52 of the elastic body 50 is inserted into and fixed to is formed at the channel 41. At that time, a part of the fixing member 52 of the elastic body 50 is inserted into and fixed to the groove 46 completely. The supporting member 51 of the elastic body 50 and A part of the fixing member 52 connected to the supporting member 51 are formed with a space (the channel 41) to be contracted, expanded and restored by external force. When the elastic body 50 is inserted into the channel 41 and coupled to the contact pin 20, the first contact section 22 and the second contact section 23 of the contact pin 20 are appropriately out of the side surface 43 and the lower surface 44 of the housing.

FIG. 6 is a perspective and cross-sectional view showing a state that the contact pin 20 and the elastic body 50 are provided in the contact pin housing 40. As shown in FIG. 6, in the contact pin housing 40, the elastic body 50 is inserted into the channel 41, the contact pin 20 is inserted from the lower surface 44 of the slots 45 and then, the second holding projection 25 is fixed to the supporting member 51 of the elastic body 50. Then, the upper surface of the slots 45 engages with the contact pin 20 and thus, the first holding projection 24 of the contact pin 20 is fixed to the supporting member 51 of the elastic body 50. Like this, the elastic body-inserting section 21 of the contact pin 20 is coupled to the elastic body 50.

FIG. 7 is a cross-sectional view of the socket in which the contact pin housing shown in FIG. 6 is provided. In FIG. 7, after the contact pin 20 and the elastic body 50 is provided in the contact pin housing 40, the contact pin housing 40 is fixed to the lower holder 61 to be opposite to each other and the upper holder 62 is positioned at the upper side. In this state, the socket is mounted on the PCB. As shown in FIG. 7, when the contact pin housing 40 in which the contact pin 20 and the elastic body 50 are provided is mounted on the PCB terminal 60, the contact pin 20 is rotated toward the inner side of the contact pin housing 40, so that the second contact section 23 of the contact pin 20 gets in contact with the PCB terminal 60. That is, about the portion in which the supporting member 51 and the fixing member 52 of the elastic body 50, the lower portion of the supporting member 51 is rotated inside to be contracted up a little and the upper portion of the supporting member 51 and the fixing member 52 are rotated outside to be expanded up a little.

FIG. 8 is a cross-sectional view showing a state that a module is inserted into the socket shown in FIG. 7. As shown in FIG. 8, when the module 30 is inserted into the contact pin housing 40 and the connecting pin 31 of the module 30 pushes the first contact section 22 of the contact pin 20, the vertical moment and the horizontal moment are acted on the first contact section 22 and the synthesized moment serves as rotating force of the contact pin, so that a wiping action occurs in large area where the first contact section 22 and the connecting pin 31 is in contact with each other well. At that time, the second contact section 23 of the contact pin 20 is rotated and thus, a wiping action occurs in large area where the second contact section 23 is in contact with the PCB terminal 60. That is, the vertical force and the horizontal force acted on the contact pin 20 are larger than those before the module is inserted. In this state, if the module 30 is removed from the contact pin housing 40, the force before the module 30 is inserted is acted on the contact pin 20 and the elastic body 50 supporting the contact pin 20.

As described above, the socket for testing a module according to the present invention has advantages that the contacting state can be improved, the inductance of the contact pin can be reduced and the lifetime of the socket can be elongated. Particularly, because the socket for testing a module at high frequency has been imported for use at a high price, great import substitution effect and export increment can be expected.

Although technical spirits of the present invention has been disclosed with reference to the appended drawings and the preferred embodiments of the present invention corresponding to the drawings has been described, descriptions in the present specification are only for illustrative purpose, not for limiting the present invention.

Also, those who are skilled in the art will appreciate that various modifications, additions and substitutions are possible without departing from the scope and spirit of the present invention. Therefore, it should be understood that the present invention is limited only to the accompanying claims and the equivalents thereof, and includes the aforementioned modifications, additions and substitutions.

What is claimed is:

1. A contact pin which is formed of a thin and flat metal sheet and which is an electrical connecting device for mutually connecting a connecting pin of a module to a terminal of a printed circuit board in testing the module, comprising:
an elastic body-inserting section formed such that most part of either left or right side of a center of said contact pin is opened;
a first contact section opposite to said elastic body-inserting section and formed to get in contact with said connecting pin of said module; and
a second contact section formed at lower end of said elastic body-inserting section to get in contact with said terminal of said PCB,
wherein said elastic body-inserting section is formed in a shape longish from up to down and holding projections are formed at both end portions of said elastic body-inserting section, said holding projections supporting an elastic body to be inserted into said elastic body-inserting section so as not to easily separate said elastic body from said elastic body-inserting section.

2. A contact pin according to claim 1, wherein said first contact section has a shape of a curved surface to maintain wiping with said connecting pin of said module in large area.

3. A contact pin according to claim 1, wherein said second contact section has a shape of a curved surface to maintain wiping with said terminal of said PCB in large area.

4. A contact pin according to claim 2, wherein said second contact section has a shape of a curved surface to maintain wiping with said terminal of said PCB in large area.

5. A elastic body for supporting a contact pin which is an electrical connecting device for mutually connecting a connecting pin of a module to a terminal of a printed circuit board (PCB) in testing the module, comprising:
a supporting member formed in a shape longish from up to down to be inserted into and fixed to a contact pin inserting section of a contact pin, said contact pin inserting section having a space of a shape longish from up to down and holding projections formed at both end portions thereof, respectively; and
a fixing member formed as one body with said supporting member and perpendicularly to said supporting member at a upper portion of said supporting member, said fixing member being inserted into and fixed to a contact pin housing for fixing said contact pin,
wherein said elastic body provides an elastic force and a restoring force to said contact pin, by way of being contracted, expanded and restored about a portion where said supporting member and said fixing member are crossed.

6. A socket for testing a module, including a contact pin housing equipped with a contact pin that is an electrical connecting device for mutually connecting a connecting pin of the module to a terminal of a printed circuit board (PCB) in testing the module and an elastic body for supporting said contact pin, and comprising:
one or more slots formed in said contact pin housing, said slots penetrating said contact pin housing from up to down with one side thereof opened and having a room other than a room for receiving said contact pin; and
a channel formed with a groove for fixing said elastic body and formed at a center of said contact pin housing along a length direction thereof to cross all of said slots,
wherein said elastic body is inserted into said channel and consists of a supporting member formed in a shape longish from up to down and a fixing member formed as one body with said supporting member and formed perpendicularly to said supporting member at a upper portion of said supporting member, to be fixed to said groove and to serve as a rotating axis of said contact pin, and
wherein said contact pin includes an elastic body-inserting section formed in a shape longish from up to down to be coupled to said supporting member of said elastic body and having holding projections formed at both end portions thereof not to easily separate said elastic body from said elastic body-inserting section, said contact pin being inserted into said slots and being supported by said elastic body to electrically connect said connecting pin of said module to said terminal of said PCB.
